(19) United States
(12) Patent Application Publication
(10) Pub. No.: US 2017/0025611 A1
(43) Pub. Date: Jan. 26, 2017

(54) MASK AND METHOD FOR MANUFACTURING DISPLAY PANEL

(71) Applicant: EVERDISPLAY OPTRONICS (SHANGHAI) LIMITED, SHANGHAI CITY (CN)

(72) Inventor: Chun-Chieh HUANG, SHANGHAI CITY (CN)

(21) Appl. No.: 15/137,178

(22) Filed: Apr. 25, 2016

(30) Foreign Application Priority Data
Jul. 24, 2015 (CN) 201510439851.0

(51) Int. Cl. H01L 51/00; H01L 27/32; B05B 15/04; H01L 51/56

(52) U.S. Cl. CPC H01L 51/0011; H01L 51/56; H01L 51/001; H01L 27/3246; H01L 27/3283; B05B 15/045; H01L 51/5012

(57) ABSTRACT

The present disclosure relates to a mask and a method for manufacturing a display panel. The mask includes: a body provided with a plurality of openings for defining pixel patterns and partition areas each of which is located among adjacent openings; and at least partition member provided on the partition areas. Using the mask and manufacturing provided by the present disclosure, pixel color mixing can be reduced.

### CROSS-REFERENCE TO RELATED APPLICATIONS

This application claims priority to Chinese Patent Application No. 201510439851.0, filed Jul. 24, 2015, the entire contents of which are incorporated herein by reference.

### TECHNICAL FIELD

The present disclosure generally relates to display technologies, and more particularly to a mask and a method for manufacturing a display panel.

### BACKGROUND

Recently, with rapid development, Organic Light Emitting Diode (OLED) technology has become the most promising technology which may replace Liquid Crystal Displays (LCDs).

When manufacturing an OLED substrate, respective layers in the organic light emitting device are formed by evaporation. Generally, masks having openings corresponding to thin film patterns to be formed are used to form thin film patterns corresponding to pixels on the substrate. In order to form the openings corresponding to the fine thin film patterns, masks usually have a very small thickness, and intervals between openings become very small. During processing, such masks are inclined to be deformed, thereby resulting in pixel color mixing.

Color mixing is one of the defects which influence the yield of OLED products. Specifically, after a mask is stretched, the mask is not fully attached and in parallel with the substrate or some local unevenness occurs, and thus during evaporation, organic materials may deviate the desired positions and laterally diffuse to adjacent pixel areas. As a result, color mixing occurs. Further, with the increasing of resolution the display panels, the color mixing becomes more serious.

### SUMMARY

Aiming at the defects in related arts, embodiments of the present disclosure provide a mask and a method for manufacturing a display panel to reduce pixel color mixing.

According to an aspect of embodiments of the present disclosure, there is provided a mask, including:

a body provided with a plurality of openings for defining pixel patterns and partition areas each of which is located among adjacent openings; and

at least partition member provided on the partition areas.

Optionally, at least a part of the openings are located on a plurality of closed areas formed by the partition areas, wherein one of the closed areas corresponds to one of the openings.

Optionally, more than one partition members are provided on the partition areas, and each partition member is located between two adjacent openings.

Optionally, more than one partition members are provided on the partition areas, and each partition member is located among four adjacent openings.

Optionally, edges of the partition members are adaptive to edges of the openings.

Optionally, the plurality of openings are arranged as an array in rows and columns, and each of the partition members is located between two adjacent rows and columns.

Optionally, the partition members are formed on the partition areas of the body by etching.

Optionally, the partition members are made of organic photoresist.

Optionally, the mask is a metal mask.

According to another aspect of embodiments of the present disclosure, there is provided a method for manufacturing a display panel using a mask, wherein the mask includes:

a body provided with a plurality of openings for defining pixel patterns and partition areas each of which is located among adjacent openings; and

at least one partition member provided on the partition areas;

wherein the method includes:

providing a substrate; and

performing evaporation on the substrate using the mask with the partition member facing the substrate, so as to form thin films for pixels on the substrate.

Optionally, the step of evaporation includes:

putting the mask over the substrate with the partition member facing the substrate; and

performing evaporation on the substrate to make resultant adjacent sub-pixels isolated from each other.

In the embodiments of the present disclosure, at least one partition member for separating thin film patterns which are to be formed according to openings in a mask is formed on the mask. Thus, the present disclosure can avoid the problem that organic materials may deviate the desired positions and laterally diffuse to adjacent pixel areas, and thereby the color mixing of the display panel can be reduced. Further, because the mask has partition members for separating thin film patterns which are to be formed according to openings in the mask, the intervals between adjacent pixels of the same or different colors can be reduced to improve resolution of the display panel.

### BRIEF DESCRIPTION OF THE DRAWINGS

The above and other features and advantages of the present disclosure will become apparent from the following description of the exemplary embodiments with reference to drawings.

FIG. 1 is a schematic diagram showing a mask according to an embodiment of the present disclosure.

FIGS. 2A to 2C are schematic diagrams showing partition members and openings according to embodiments of the present disclosure.

FIG. 3 is a schematic diagram showing a mask according to another embodiment of the present disclosure.

FIG. 4 is a schematic diagram showing a mask according to another embodiment of the present disclosure.

FIG. 5 is a schematic diagram showing evaporation using the mask according an embodiment of the present disclosure.

### REFERENCE SIGNS

100, 200, 300, 400 body
110, 110′, 110″, 210, 310 openings
120, 120′, 120″, 220, 320, 420 partition members
121, 121′ curved edge
122″ bent-line-shaped edge
500 substrate
600 thin film for pixels

### DETAILED DESCRIPTION

Now, exemplary implementations will be described more comprehensively with reference to the accompanying drawings. However, the exemplary implementations may be carried out in various manners, and shall not be interpreted as being limited to the implementations set forth herein; instead, providing these implementations will make the present disclosure more comprehensive and complete and will fully convey the conception of the exemplary implementations to the ordinary skills in this art. Throughout the drawings, the like reference numbers refer to the same or the like structures, and repeated descriptions will be omitted.

The features, structures or characteristics described herein may be combined in one or more embodiments in any suitable manner. In the following descriptions, many specific details are provided to facilitate sufficient understanding of the embodiments of the present disclosure. However, one of ordinary skills in this art will appreciate that the technical solutions in the present disclosure may be practiced without one or more of the specific details, or by employing other methods, components, materials and so on. In other conditions, well-known structures, materials or operations are not shown or described in detail so as to avoid confusion of respective aspects of the present disclosure.

The drawings of the present disclosure are only for illustrating relative position relationships, and the sizes of some portions are shown exaggeratedly to facilitate understanding, and however the sizes in the drawings do not indicate real proportional relations.

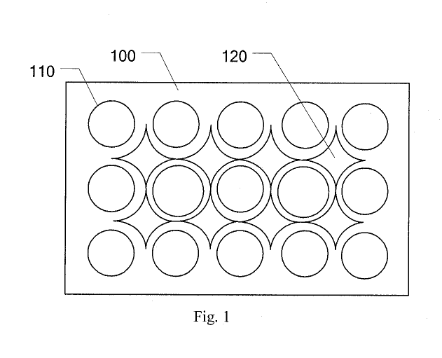

In order to avoid pixel color mixing, the present disclosure provides a mask used in evaporation process for manufacturing a display panel. Optionally, the mask may be a metal mask. FIG. 1 is a schematic diagram showing a mask of the present disclosure. The mask includes a body 100 having a plurality of openings 110 and partition areas. The openings 110 define thin film patterns, for example, pixel patterns. The openings 110 may have a circular shape, a rectangular shape, a diamond shape, a trapezoid shape, or other abnormal shape, and accordingly the thin film patterns formed by evaporation using the mask have a circular shape, a rectangular shape, a diamond shape, a trapezoid shape, or other abnormal shape. The plurality of openings 110 are arranged as an array along row and column directions, so that a pixel array may be formed in the evaporation process for manufacturing a display panel. Each of the partition areas is located between adjacent openings 110. There are a plurality of partition members 120 provided on the partition areas. Optionally, the partition members 120 are made of organic photoresist, and are formed on the body 100 by etching. The plurality of partition members 120 are located between adjacent openings 110 so as to separate the pixel patterns to be formed according to the openings 110.

At least a part of the openings 110 are located on a plurality of closed areas formed by the partition areas. Specifically, in the embodiment, each of the partition members 120 is located among four adjacent openings 110. A part of the openings 110 are located in closed areas formed by four partition members 120 adjacent to respective openings 110. One closed area only accommodate one opening 110. For example, an opening 110 located in the center of the array is within a closed area formed by four partition members 120 which are adjacent to the opening 110, and openings 110 at edges of the array are separated from other openings 110 by one or two partition members 120 which are adjacent to the openings 110.

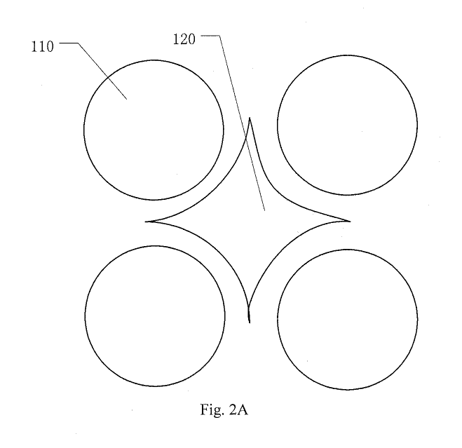

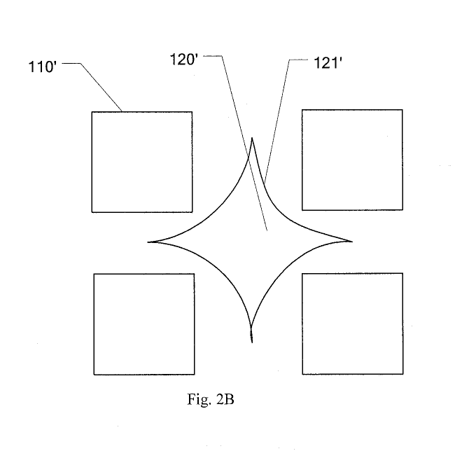

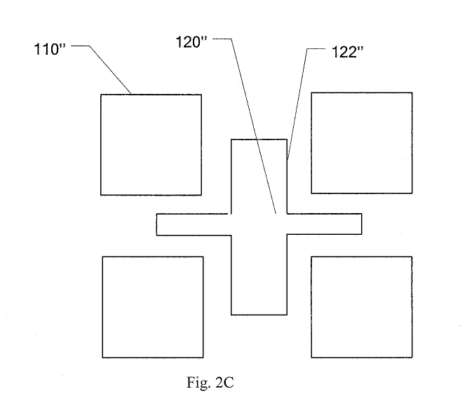

Specifically, an edge of each partition members 120 which faces an adjacent opening 110 has a shape adaptive to the shape of the opening 110. Referring to FIG. 2A, respective openings 110 have a circular shape, and the partition member 120 located among four circular openings 110 has four curved edges (for example, arched or rounded, i.e., the edges are curved at a curvature adaptive to the shape of the openings 110) 121 facing the four circular openings 110, respectively. Optionally, the curved edges 120 and the circular openings 110 which the curved edges 120 face are concentric, and the radius of each curved edge 120 is greater than the radius of each circular opening 110. In an embodiment, the central angle of each curved edge 121 is 90°. In some other embodiments, the central angle of each curved edge 121 may be smaller than 90°.

FIG. 2B is a mask according to an embodiment of the present disclosure. The mask in FIG. 2B is similar to that in FIG. 2A, and each partition members 120′ is located among four adjacent openings 110′. However, in this embodiment, the edge of each partition members 120 which faces an adjacent opening 110′ does not have a shape adaptive to the shape of the opening 110′. For example, the openings 110′ have a rectangular shape, and the partition member 120′ located among four rectangular openings 110′ has four curved edges 121′ facing the four rectangular openings 110′, respectively. Optionally, each curved edge 121′ and a rectangular opening 110′ which the curved edge 121′ faces have the same center.

FIG. 2C is a mask according to an embodiment of the present disclosure. The mask in FIG. 2C is similar to that in FIG. 2B, and each partition member 120″ is located among four adjacent openings 110″. And, in this embodiment, the edge of each partition members 120″ which faces an adjacent opening 110″ has a shape adaptive to the shape of the opening 110″. For example, the openings 110″ have a rectangular shape, and the partition member 120″ located among four rectangular openings 110″ has four bent-line-shaped edges 122″ facing the four rectangular openings 110″, respectively. Optionally, each bent-line-shaped edge 122″ has two edge portions in parallel with the long and short edges of a rectangular opening 110″, respectively. Each bent-line-shaped edge 122″ and a rectangular opening 110″ which the bent-line-shaped edge 122″ faces have the same center.

Specifically, in the embodiments in FIGS. 2A, 2B and 2C, four partition members which are adjacent to the same opening are bonded, so that the opening is located in a closed area formed by the four adjacent partition members.

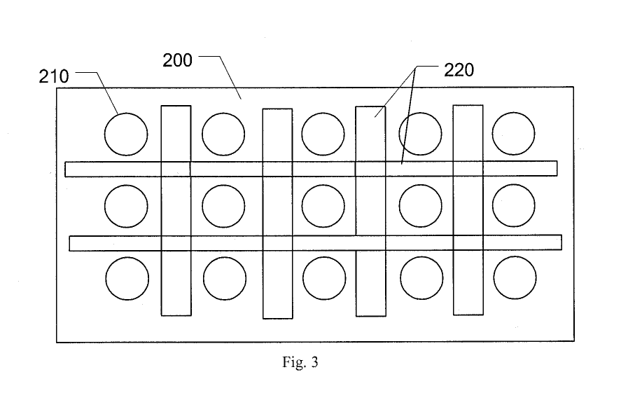

FIG. 3 is a schematic diagram showing a mask according to an embodiment of the present disclosure. Similarly to FIG. 1, the mask in FIG. 3 includes a body 200 provided with a plurality of openings 210 and partition areas, and one or more partition members 220 provided on the partition areas. The openings 210 define a plurality of pixel patterns. The plurality of openings 210 are arranged in an array along row and column directions, so that a pixel array may be formed in the evaporation process for manufacturing a display panel. Each of the partition members 220 is located between two openings which are adjacent in the row direction and/or the column direction.

Specifically, a part of the openings 210 are located in closed areas formed by four partition members 220 which are adjacent to the openings 210. One closed area only accommodates one opening 210. For example, an opening 210 located in the center of the array is within a closed area formed by four partition members 220 which are adjacent to the opening 210, and openings 210 at edges of the array are separated from other openings 210 by two or three partition members 220 which are adjacent to the openings 210.

In the embodiment, the edge of each partition members 220 which faces an adjacent opening 210 has a shape different from the shape of the opening 210. For example, the openings 210 may have a circular shape, and the edges of the partition members 220 are straight-line shaped. In some modified embodiments, the edge of each partition members 220 which faces an adjacent opening 210 has a shape adaptive to the shape of the opening 210. For example, the openings 210 have a rectangular shape, and the edges of the partition members 220 are straight-line-shaped edges which are in parallel with the edges of the adjacent rectangular openings.

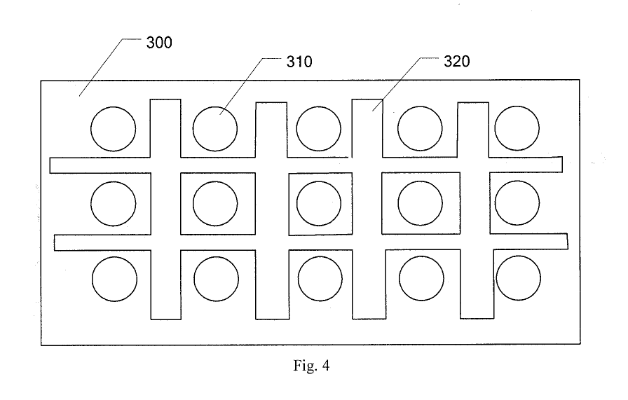

FIG. 4 is a schematic diagram showing a mask according to an embodiment of the present disclosure. Similarly to FIG. 3, the mask in FIG. 4 includes a body 300 provided with a plurality of openings 310 and partition areas, and one or more partition members 320 provided on the partition areas. The openings 310 define a plurality of pixel patterns. The plurality of openings 310 are arranged in an array along row and column directions, so that a pixel array may be formed in the evaporation process for manufacturing a display panel. Each of the partition members 320 is located between two openings 310 which are adjacent in the row direction and/or the column direction (i.e., each partition members 320 is located between two adjacent opening rows or two adjacent opening columns).

Although some exemplary embodiments are described above, one of ordinary skill in this art can arrive at more modified embodiments based on the descriptions elaborated herein. For example, the openings may have a circular shape, a rectangular shape, a diamond shape, a trapezoid shape, or other abnormal shape, or the shapes of the openings may be different. For example, in the array formed by openings, the openings rows may be staggered. As another example, the row direction and the column direction in the array may not be perpendicular with each other. For such openings having different shapes and modified arrangement, different partition members may be used to separate thin film patterns to be formed according to the openings, and repeated descriptions are omitted herein.

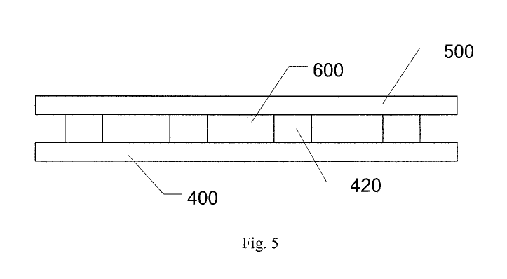

In the present disclosure, the mask may be used in evaporation process for manufacturing a display panel. FIG. 5 is a method for manufacturing a display panel according to an embodiment of the present disclosure. The method may include the following steps. Firstly, a substrate 500 is provided. Then, evaporation is performed on the substrate 500 using the mask provided by the present disclosure to form thin films 600 for pixels. During evaporation, the partition members 420 face the substrate 500, so that the resultant adjacent sub-pixels in the thin films 600 for pixels can be isolated from each other. It shall be noted, for convenience in description, details regarding steps such as cleaning, etching and/or packaging for manufacturing the display panel are omitted, and these steps may be found in related arts.

In the embodiments of the present disclosure, partition members for separating thin film patterns which are to be formed according to openings in a mask are formed on the mask. Thus, the present disclosure can avoid the problem that organic materials may deviate the desired positions and laterally diffuse to adjacent pixel areas, and thereby the color mixing of the display panel can be reduced. Further, because the mask has partition members for separating thin film patterns which are to be formed according to openings in the mask, the intervals between adjacent pixels of the same or different colors are allowed be reduced to improve resolution of the display panel.

The above detailed descriptions relate to some possible implementations of the present disclosure, and however they are not for limiting the protection scope of the present disclosure, and any equivalent implementations or modifications without departing the spirit of the present disclosure shall fall within the protection scope of the present disclosure.

What is claimed is:

1. A mask, comprising:
a body provided with a plurality of openings for defining pixel patterns and partition areas each of which is located among adjacent openings; and
at least one partition member provided on the partition areas.

2. The mask according to claim 1, wherein at least a part of the openings are located on a plurality of closed areas formed by the partition areas, wherein one of the closed areas corresponds to one of the openings.

3. The mask according to claim 1, wherein more than one partition members are provided on the partition areas, and each partition member is located between two adjacent openings.

4. The mask according to claim 2, wherein more than one partition members are provided on the partition areas, and each partition member is located between two adjacent openings.

5. The mask according to claim 1, wherein more than one partition members are provided on the partition areas, and each partition member is located among four adjacent openings.

6. The mask according to claim 2, wherein more than one partition members are provided on the partition areas, and each partition member is located among four adjacent openings.

7. The mask according to claim 3, wherein edges of the partition members are adaptive to edges of the openings.

8. The mask according to claim 4, wherein edges of the partition members are adaptive to edges of the openings.

9. The mask according to claim 5, wherein edges of the partition members are adaptive to edges of the openings.

10. The mask according to claim 6, wherein edges of the partition members are adaptive to edges of the openings.

11. The mask according to claim 1, wherein the plurality of openings are arranged as an array in rows and columns, and each of the partition members is located between two adjacent rows and columns.

12. The mask according to claim 2, wherein the plurality of openings are arranged as an array in rows and columns, and each of the partition members is located between two adjacent rows and columns.

13. The mask according to claim 1, wherein the partition members are formed on the partition areas of the body by etching.

14. The mask according to claim 2, wherein the partition members are formed on the partition areas of the body by etching.

15. The mask according to claim 13, wherein the partition members are made of organic photoresist.

16. The mask according to claim 1, wherein the mask is a metal mask.

17. The mask according to claim 2, wherein the mask is a metal mask.

18. A method for manufacturing a display panel using a mask, wherein the mask comprises:
a body provided with a plurality of openings for defining pixel patterns and partition areas each of which is located among adjacent openings; and
at least one partition member provided on the partition areas;
wherein the method comprises:
providing a substrate; and
performing evaporation on the substrate using the mask with the at least one partition member facing the substrate, so as to form thin films for pixels on the substrate.

19. The method according to claim 18, wherein the step of evaporation comprises:
putting the mask over the substrate with the at least one partition member facing the substrate; and
performing evaporation on the substrate to make resultant adjacent sub-pixels isolated from each other.

20. The method according to claim 18, wherein at least a part of the openings in the mask are located on a plurality of closed areas formed by the partition areas, wherein one of the closed areas corresponds to one of the openings.
